(19) United States
(12) Patent Application Publication
(10) Pub. No.: US 2015/0187798 A1
(43) Pub. Date: Jul. 2, 2015

(54) DISPLAY DEVICE AND REPAIR METHOD THEREOF

(71) Applicant: Samsung Display Co., Ltd., Yongin-City (KR)

(72) Inventors: Dong-Hyun YOO, Hwaseong-si (KR); Seong Young LEE, Hwaseong-si (KR); Bo Yeong KIM, Asan-si (KR); Hyung Jun PARK, Seongnam-si (KR)

(73) Assignee: Samsung Display Co., Ltd., Yongin-City (KR)

(21) Appl. No.: 14/293,585

(22) Filed: Jun. 2, 2014

(30) Foreign Application Priority Data
Dec. 30, 2013 (KR) 10-2013-0167562

(51) Int. Cl. H01L 27/12; H01L 23/538

(52) U.S. Cl. CPC H01L 27/124; H01L 23/5381; H01L 27/1259

(57) ABSTRACT

A display device includes: a substrate; a gate electrode on the substrate; a first electrode separated from the gate electrode; a gate insulating layer on the gate electrode and the first electrode; a semiconductor on the gate electrode; a source electrode and a drain electrode on the semiconductor and separated from each other; a passivation layer on the source electrode and the drain electrode; a first contact hole defined in the passivation layer and exposing the drain electrode; a second contact hole defined in the passivation layer and exposing the first electrode; a pixel electrode on the passivation layer and connected to the drain electrode through the first contact hole; and a second electrode on the passivation layer and connected to the first electrode through the second contact hole. The first electrode overlaps the drain electrode.

This application claims priority to Korean Patent Application No. 10-2013-0167562 filed on Dec. 30, 2013, and all the benefits accruing therefrom under 35 U.S.C. §119, the entire contents of which are incorporated herein by reference.

### BACKGROUND

(a) Field

The invention relates to a display device and a repair method thereof. More particularly, the invention relates to a display device on which a repair process is performed while minimizing a reduction of an aperture ratio thereof, and a repair method thereof.

(b) Description of the Related Art

Liquid crystal displays (“LCDs”) are one of the most widely used flat panel displays. An LCD includes a pair of panels provided with field-generating electrodes, and a liquid crystal (“LC”) layer interposed between the two panels. The LCD displays images by applying signals to the field-generating electrodes to generate an electric field in the LC layer that determines the orientation of LC molecules therein to adjust polarization of incident light.

As one of two panels forming the liquid crystal display, a thin film transistor (“TFT”) array panel is used as a circuit board to independently drive each pixel in the LCD or an organic light emitting device including an organic light emitting diode (“OLED”).

The TFT array panel includes signal lines such as a gate line transmitting a gate signal and a data line transmitting a data signal and intersecting the gate line, a TFT connected to the gate line and the data line, and a pixel electrode connected to the TFT.

### SUMMARY

When signal lines of a display device such as a liquid crystal display (“LCD”) device are disconnected or shorted, a pixel corresponding to the signal lines is damaged such that repair to the damaged pixel is necessary. However, the aperture ratio of the LCD is reduced due to an electrode pattern disposed in the LCD for the repair process.

One or more exemplary embodiment of the invention provides a display device on which a repair process is performed while minimizing a reduction of an aperture ratio thereof, and a repair method thereof.

An exemplary embodiment of a display device according to the invention includes: a substrate; a gate electrode on the substrate; a first electrode separated from the gate electrode; a gate insulating layer on the gate electrode and the first electrode; a semiconductor on the gate electrode; a source electrode and a drain electrode on the semiconductor and separated from each other; a passivation layer on the source electrode and the drain electrode; a first contact hole defined in the passivation layer and exposing the drain electrode; a second contact hole defined in the passivation layer and exposing the first electrode; a pixel electrode on the passivation layer and connected to the drain electrode through the first contact hole; and a second electrode on the passivation layer and connected to the first electrode through the second contact hole. The first electrode overlaps the drain electrode.

The first electrode may include a first end portion overlapping the second electrode, a second end portion overlapping the drain electrode, and a connection member connecting the first end portion and the second end portion to each other.

The drain electrode may include a first portion overlapping the gate electrode, a second portion overlapping the pixel electrode, and a third portion overlapping the second end portion of the first electrode.

The first electrode may be in the same layer as the gate electrode.

The second electrode may be in the same layer as the pixel electrode.

A storage electrode line on the passivation layer may be further included, and the second electrode may be connected to the storage electrode line.

A gate line and a data line on the substrate may be further included, and the gate electrode may be connected to the gate line, while the source electrode may be connected to the data line.

The storage electrode line may extend in a direction parallel to that of the data line.

The storage electrode line may overlap the data line.

The first electrode may include a first end portion overlapping the second electrode, a second end portion overlapping the drain electrode, and a connection member connecting the first end portion and the end second portion to each other. The connection member may extend in a direction parallel to that of the storage electrode line.

A method of repairing a display device includes: short-circuiting a first electrode and a drain electrode of the display device. The display device includes: a substrate; a gate electrode on the substrate; the first electrode separated from the gate electrode; a gate insulating layer on the gate electrode and the first electrode; a semiconductor on the gate electrode; a source electrode and the drain electrode on the semiconductor and separated from each other; a passivation layer on the source electrode and the drain electrode; a first contact hole defined in the passivation layer and exposing the drain electrode; a second contact hole defined in the passivation layer and exposing the first electrode; a pixel electrode on the passivation layer and connected to the drain electrode through the first contact hole; and a second electrode on the passivation layer and connected to the first electrode through the second contact hole. The first electrode overlaps the drain electrode.

The first electrode may include a first end portion overlapping the second electrode, a second end portion overlapping the drain electrode, and a connection member connecting the first end portion and the second end portion to each other. A laser may be irradiated to the second end portion of the first electrode in the short-circuiting of the first electrode and the drain electrode.

The drain electrode may include a first portion overlapping the gate electrode, a second portion overlapping the pixel electrode, and a third portion overlapping the second end portion of the first electrode. A laser may be irradiated to the third portion of the drain electrode in the short-circuiting of the first electrode and the drain electrode.

The first electrode may be in the same layer as the gate electrode.

The second electrode may be in the same layer as the pixel electrode.

A storage electrode line on the passivation layer may be further included in the display device, and the second electrode may be connected to the storage electrode line.

A gate line and a data line on the substrate may be further included in the display device, the gate electrode may be connected to the gate line, and the source electrode may be connected to the data line.

The storage electrode line may extend in a direction parallel to that of the data line.

The storage electrode line may overlap the data line.

The first electrode may include a first end portion overlapping the second electrode, a second end portion overlapping the drain electrode, and a connection member connecting the first end portion and the second end portion. The connection member may extend in a direction parallel to that of the storage electrode line.

One or more exemplary embodiment of the display device and the repair method thereof according to the invention may provide the repair process while minimizing a reduction of the aperture ratio of the display device.

### BRIEF DESCRIPTION OF THE DRAWINGS

The above and other features of this disclosure will become more apparent by describing in further detail exemplary embodiments thereof with reference to the accompanying drawings, in which:

FIG. 1 is a top plan view of an exemplary embodiment of a display device according to the invention.

FIG. 2 is a top plan view of an exemplary embodiment of an enlarged portion of the display device of FIG. 1 according to the invention.

FIG. 3 is a cross-sectional view of the display device of FIG. 2 taken along line III-III.

FIG. 4 is a top plan view of a partial layer in FIG. 2.

FIG. 5 is a top plan view of another partial layer in FIG. 2.

FIG. 6 is a top plan view of an exemplary embodiment of a repair area in a display device according to the invention.

FIG. 7 is a cross-sectional view of the display device of FIG. 6 taken along line VII-VII.

### DETAILED DESCRIPTION

The invention will be described more fully hereinafter with reference to the accompanying drawings, in which exemplary embodiments of the invention are shown. As those skilled in the art would realize, the described exemplary embodiments may be modified in various different ways, all without departing from the spirit or scope of the invention. In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, connected (and separated) may refer to elements being physically and/or electrically connected to (or separated from) each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

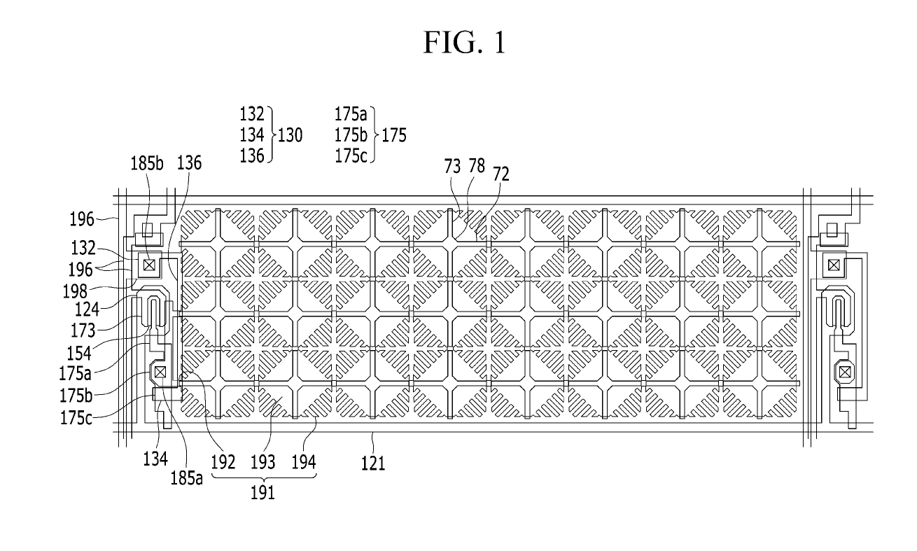

Firstly, a display device according to invention will be described with reference to FIG. 1 to FIG. 5.

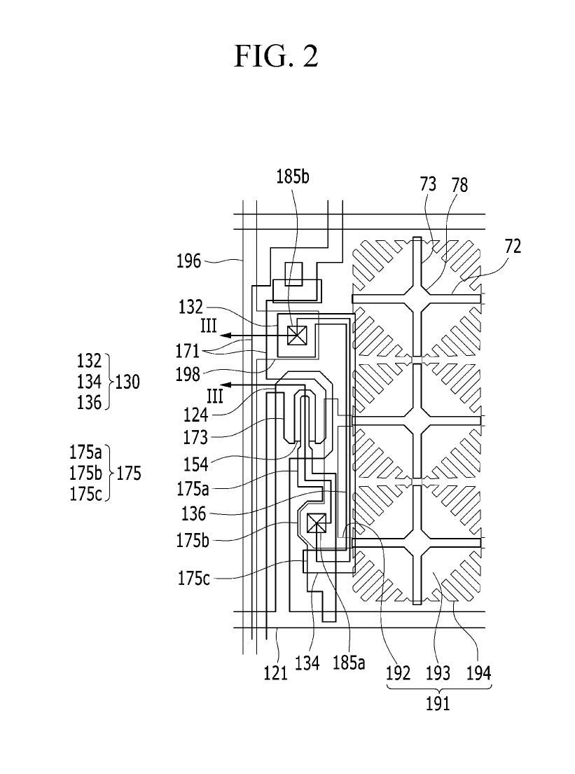

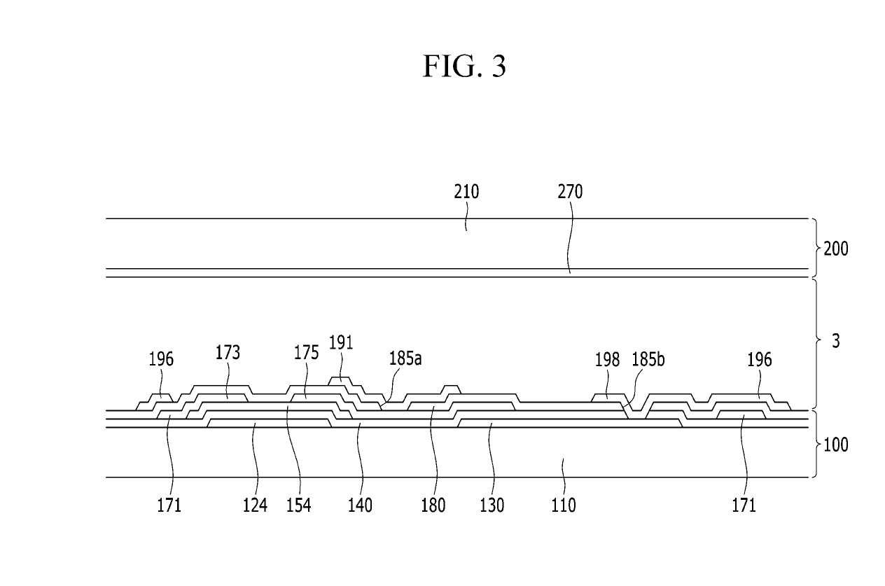

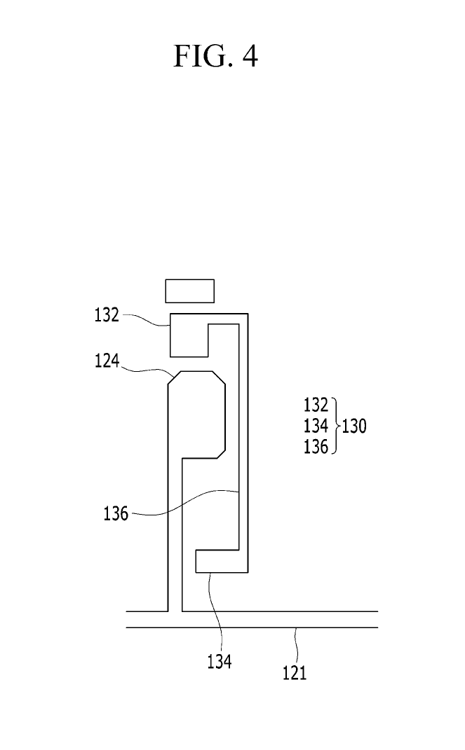

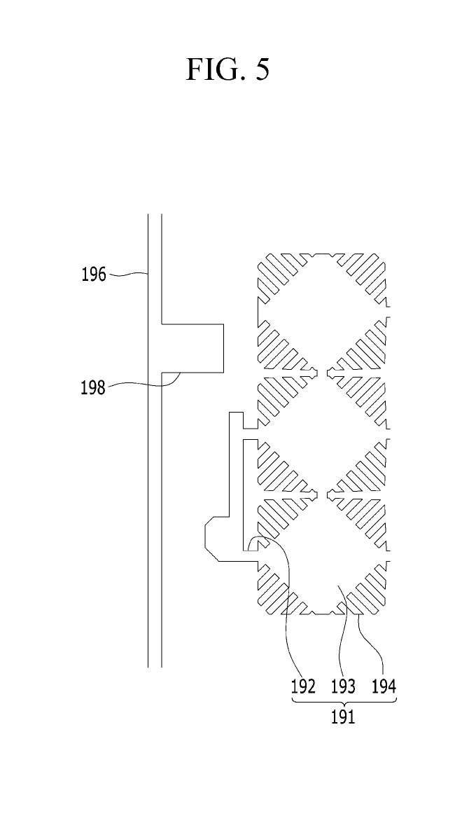

FIG. 1 is a top plan view of an exemplary embodiment of a display device according to the invention, FIG. 2 is a top plan view of an exemplary embodiment of an enlarged portion of a display device according to the invention, and FIG. 3 is a cross-sectional view of the display device of FIG. 2 taken along line III-III. FIG. 4 is a top plan view of a partial layer in FIG. 2, and FIG. 5 is a top plan view of another partial layer in FIG. 2.

A display device includes a lower (display) panel 100 and upper (display) panel 200 facing each other, and a liquid crystal layer 3 interposed between two display panels 100 and 200.

Firstly, the lower panel 100 will be described.

A gate line 121 is disposed to extend a first direction on a first substrate 110. The first substrate 110 may include transparent glass or plastic. A gate electrode 124 connected to the gate line 121 is disposed on the first substrate 110. The display device may include a plurality of gate lines 121 extends in an approximate transverse direction in the top plan view and is disposed with a predetermined interval therebetween. The gate electrode 124 may be disposed at an approximate center between two adjacent gate lines 121 and be connected to one of the two adjacent gate lines 121.

A first electrode 130 separated from the gate line 121 and the gate electrode 124 is disposed on the first substrate 110. The first electrode 130 is spaced apart from the gate line 121 and the gate electrode 124 in the top plan view. The first electrode 130 may be disposed in the same layer and include the same material as the gate line 121 and the gate electrode 124. In an exemplary embodiment of manufacturing the display device, the first electrode 130 may be formed in a process of forming the gate line 121 and the gate electrode 124, such that the first electrode 130 is in the same layer and include the same material as the gate line 121 and the gate electrode 124.

The first electrode 130 includes a first end portion 132 and a second end portion 134 positioned at opposing sides of the gate electrode 124, and a connection member 136 connecting the first end portion 132 and the second end portion 134 to each other. In an exemplary embodiment, for example, the first end portion 132 is disposed at a first (e.g., upper in the plan view) side of the gate electrode 124 and separated from the gate electrode 124, and the second end portion 134 is disposed at an opposing second (e.g., lower in the plan view) side of the gate electrode 124 and separated from the gate electrode 124. The connection member 136 is disposed to enclose the gate electrode 124 while being separated from the gate electrode 124, and to connect the first end portion 132 and the second end portion 134 to each other.

FIG. 4 shows the gate line 121, the gate electrode 124 and the first electrode 130 disposed in the same layer of the lower panel 100. For both single and multilayer structures, the gate line 121, the gate electrode 124 and the first electrode 130 may be considered as disposed in the same single layer of the lower panel 100.

The gate line 121, the gate electrode 124 and the first electrode 130 may include an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, or chromium (Cr), tantalum (Ta), titanium (Ti), or the like. The gate line 121, the gate electrode 124 and the first electrode 130 may have a single layer structure, or a multilayer structure including at least two conductive layers having different physical properties.

A gate insulating layer 140 including silicon nitride (SiNx) or silicon oxide (SiOx) is disposed on the gate line 121, the gate electrode 124 and the first electrode 130. The gate insulating layer 140 may have a multilayer structure including at least two insulating layers having different physical properties.

A semiconductor 154 is disposed on the gate insulating layer 140. The semiconductor 154 may include amorphous silicon, polycrystalline silicon, or a metal oxide.

An ohmic contact member (not shown) is disposed on the semiconductor 154. The ohmic contact may include a material such as n+ hydrogenated amorphous silicon in which an n-type impurity such as phosphorus is doped with a high concentration, or of a silicide.

A data line 171 is disposed in a second direction crossing the first direction, on the semiconductor 154 and the gate insulating layer 140. A source electrode 173 is connected to the data line 171 and a drain electrode 175 separated from the source electrode 173 are disposed on the first substrate 110. The source electrode 173 and the drain electrode 175 are separated from each other with respect to the gate electrode 124.

The display device may include a plurality of data lines 171 which extends in an approximate longitudinal direction in the top plan view and is disposed with a predetermined interval therebetween. The source electrode 173 protrudes from the data line 171 thereby forming a ‘C’ shape, and may be positioned on (e.g., overlapping) the gate electrode 124.

The drain electrode 175 includes a first portion 175a overlapping the gate electrode 124, a second portion 175b positioned between the gate electrode 124 and the first electrode 130, and a third portion 175c overlapping the first electrode 130.

The first portion 175a of the drain electrode 175 may be enclosed by the source electrode 173 in the top plan view. The second portion 175b of the drain electrode 175 may be positioned between the gate electrode 124 and the second end portion 134 of the first electrode 130, or may not overlap the gate electrode 124 and the first electrode 130. The third portion 175c of the drain electrode 175 may overlap the second end portion 134 of the first electrode 130. The second portion 175b of the drain electrode 175 may be positioned between the first portion 175a and the third portion 175c. The first to third portions 175a to 175c may collectively form a single, unitary, indivisible drain electrode 175.

The data line 171, the source electrode 173 and the drain electrode 175 may be disposed in the same layer of the lower panel 100. For both single and multilayer structures, the data line 171, the source electrode 173 and the drain electrode 175 may be considered as disposed in the same single layer of the lower panel 100.

The data line 171, the source electrode 173 and the drain electrode 175 may include a relatively low electrical resistance metal material. In an exemplary embodiment, for example, the source electrode 173 and the drain electrode 175 may include at least one of copper (Cu), aluminum (Al), silver (Ag), molybdenum (Mo), chromium (Cr), gold (Au), platinum (Pt), palladium (Pd), tantalum (Ta), tungsten (W), titanium (Ti), nickel (Ni), and alloys thereof. Further, the source electrode 173 and the drain electrode 175 may have a single layer structure or a multilayer structure. That is, the source electrode 173 and the drain electrode 175 may have a multilayer structure including two layers (e.g., double layer), three layers (e.g., triple layer), and the like which include different materials.

One gate electrode 124, one source electrode 173 and one drain electrode 175 along with the semiconductor 154 collectively form one thin film transistor (“TFT”). A channel of the TFT is formed in the semiconductor 154 which is exposed between the source electrode 173 and the drain electrode 175.

A passivation layer 180 is disposed on the data line 171, the source electrode 173, the drain electrode 175 and the exposed portion of the semiconductor 154 between the source electrode 173 and the drain electrode 175. The passivation layer 180 may include an organic insulating material or an inorganic insulating material, and may have a single layer structure or a multilayer structure.

A first contact hole 185a is defined in the passivation layer 180 and exposes the drain electrode 175. The second portion 175b of the drain electrode 175 is exposed by the first contact hole 185a.

A second contact hole 185b is defined in the gate insulating layer 140 and the passivation layer 180 and exposes the first electrode 130. The first end portion 132 of the first electrode 130 may be exposed by the second contact hole 185b.

A pixel electrode 191 connected to the drain electrode 175 through the first contact hole 185a is disposed on the passivation layer 180. Also, on the passivation layer 180, a storage electrode line 196 is extended in the second direction, and a second electrode 198 connected to the storage electrode line 196 is disposed. The second electrode 198 is connected to the first electrode 130 through the second contact hole 185b.

The pixel electrode 191 may overlap the second portion 175b of the drain electrode 175, and may be connected to the second portion 175b of the drain electrode 175. The pixel electrode 191 may not overlap the first portion 175a and the third portion 175c of the drain electrode 175.

The pixel electrode 191 may be disposed to be substantially quadrangular in the top plan view. The pixel electrode 191 overlaps the drain electrode 175 and includes a connection member 192 connected to the drain electrode 175, and a plurality of unit pixel electrodes 193 and 194 each connected to the connection member 192. The display device may include a plurality of unit pixel electrodes 193 and 194 connected to each other to collectively form a pixel electrode 191.

The display device may include a plurality of unit pixel electrodes 193 and 194 disposed in one pixel. The unit pixel electrode 193 may be otherwise referred to as a center electrode 193. The unit pixel electrode 194 may collectively formed by a plurality of minute branches 194 extending from the edge of the center electrode 193 to the outside of the pixel electrode 191 (e.g., away from the center electrode 193. The center electrode 193 may be disposed in approximate rhombus shape in the top plan view. The plurality of minute branches 194 are elongated in an extension direction and may form an angle of about 45 degrees with respect to the transverse (e.g., horizontal) direction or the longitudinal (e.g., vertical) direction, for example, an angle more than about 40 degrees to less than about 50 degrees. Also, one edge of the center electrode 193 may be orthogonal to the minute branches 194, for example, orthogonal to each of the minute branches 194.

In the above-described exemplary embodiment, the shape of the pixel electrode 191 is only one example, but the invention is not limited thereto, and numerous variations of the pixel electrode 191 are possible.

The storage electrode line 196 may be extended in a direction parallel to the data line 171 and may overlap the data line 171. A predetermined voltage may be applied to the storage electrode line 196.

The second electrode 198 protrudes from the storage electrode line 196 in the top plan view and overlaps the first electrode 130. The second electrode 198 may overlap the first end portion 132 of the first electrode 130, and may connected to the first end portion 132 of the first electrode 130. The first electrode 130 is applied with the predetermined voltage through the storage electrode line 196 and the second electrode 198.

FIG. 5 shows the pixel electrode 191, the storage electrode line 196, and the second electrode 198 disposed in the same layer of the lower panel 100.

The pixel electrode 191, the storage electrode line 196, and the second electrode 198 may include a transparent metal material such as indium-tin oxide (“ITO”) and indium-zinc oxide (“IZO”).

Although not shown, a first alignment layer may be disposed on the pixel electrode 191.

Next, the upper panel 200 will be described.

A common electrode 270 is disposed on a second substrate 210. The second substrate 210 may include transparent glass or plastic.

Openings 72, 73, and 78 as a domain division means may be defined in the common electrode 270. The openings 72, 73, and 78 includes a cross-shaped opening configured by a transverse opening 72, and a longitudinal opening 73 crossing the transverse opening 72. The openings 72, 73, and 78 may further include a center opening 78 positioned at the center portion of the cross-shaped opening. In the top plan view, the center opening 78 has a polygonal structure including four straight edge lines respectively positioned at four subregions divided by the cross-shaped opening, and in the illustrated exemplary embodiment, has a rhombus structure but is not limited thereto. The openings 72, 73, and 78 are connected to each other and may collectively form a single, unitary, indivisible opening member of the common electrode 270.

The common electrode 270 may include the transparent metal material such as ITO and IZO.

Although not shown, a second alignment layer may be disposed on the common electrode 270.

In the illustrated exemplary embodiment, the common electrode 270 is disposed in the upper panel 200, however, the invention is not limited thereto. In an alternative exemplary embodiment, the common electrode 270 may be disposed in the lower panel 100.

The liquid crystal layer 3 is disposed between the lower panel 100 and the upper panel 200. The liquid crystal layer 3 includes liquid crystal molecules. The liquid crystal molecules may have negative dielectric anisotropy and may be elongated in a direction perpendicular to the first substrate 110 in the absence of an electric field. That is, vertical alignment may be realized.

The pixel electrode 191 receives a data voltage through the data line 171 and the drain electrode 175 when the TFT is turned on, and the common electrode 270 receives a common voltage of a predetermined magnitude. By generating the electric field through the pixel electrode 191 and the common electrode 270, the arrangement direction of the liquid crystal molecules forming the liquid crystal layer 3 is determined. Polarization of light that passes through the liquid crystal layer is changed according to the orientation of liquid crystal molecules, which is determined as described above.

In the above, the exemplary embodiment of the display device according to the invention is the liquid crystal display, however, the invention is not limited thereto. The invention is not limited to the liquid crystal display and may be applied to all display devices using the TFT array panel, for example, a plasma display device and an organic light emitting device.

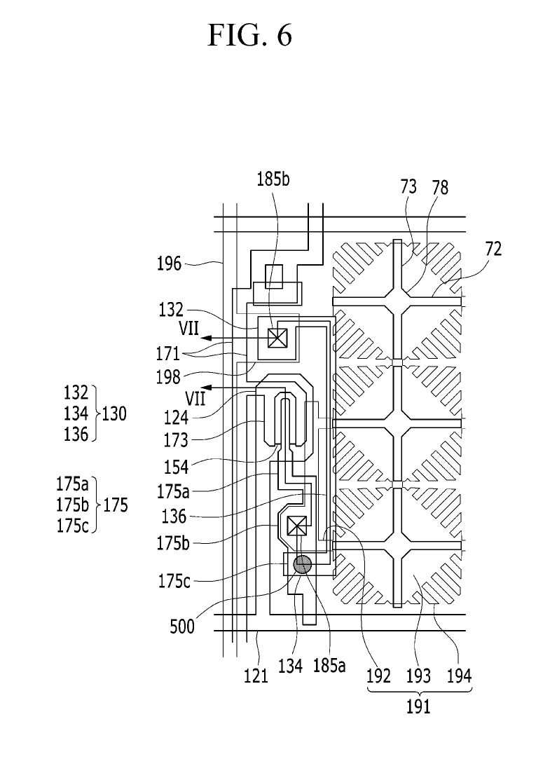

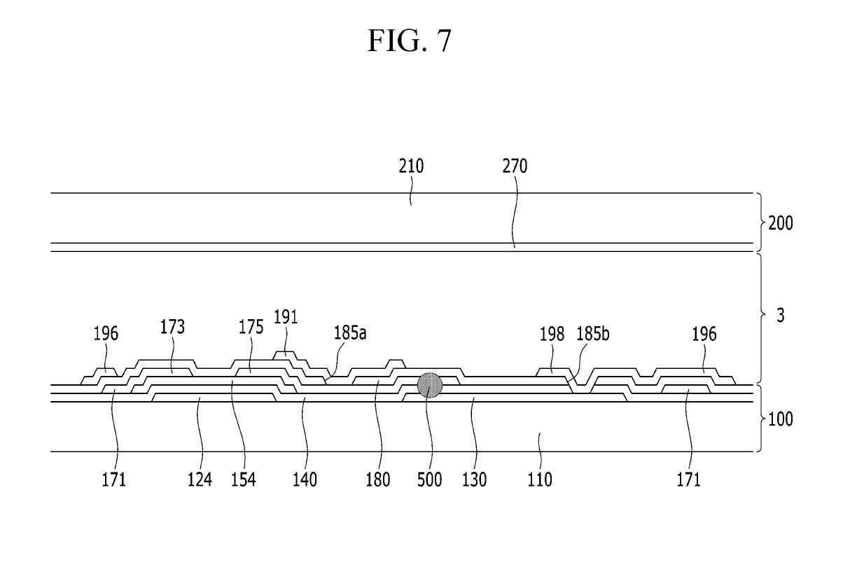

Next, a repair method of a display device according to the invention will be described with reference to FIG. 6 and FIG. 7.

FIG. 6 is a top plan view of an exemplary embodiment of a repair position in a display device according to the invention, and FIG. 7 is a cross-sectional view of the display device of FIG. 6 taken along line VII-VII.

In the exemplary embodiment of the repair position, the pixel electrode 191 may be electrically shorted to the gate electrode 124 or the gate line 121, to thereby receive a gate voltage. Also, the pixel electrode 191 may be electrically shorted to the data line 171 or the drain electrode 175, to thereby receive a data voltage. With such a repair position, the corresponding pixel as a defect in the display device is not recognized in an image when an entire screen of the display device displays a black or single color pattern. In an exemplary embodiment of the invention, to not recognize this defect, the pixel electrode 191 may be electrically connected to the storage electrode line 196.

In an exemplary embodiment of the display device according to the invention, the first electrode 130 and the drain electrode 175 overlap each other in a single pixel. In an exemplary embodiment of a method of repairing the display device, a laser 500 is irradiated to the portion where the first electrode 130 and the drain electrode 175 overlap each other to short-circuit the first electrode 130 and the drain electrode 175. At this time, the second end portion 134 of the first electrode 130 and the drain electrode 175 are overlapped with each other such that the laser 500 is irradiated to the second end portion 134 of the first electrode 130. Also, since the third portion 175c of the drain electrode 175 overlaps the first electrode 130, the laser 500 is irradiated to the third portion 175c of the drain electrode 175.

In the defective pixel, if the first electrode 130 and the drain electrode 175 are short-circuited, the voltage charged to the pixel electrode 191 may be discharged through the drain electrode 175, the first electrode 130, the second electrode 198 and the storage electrode line 196. That is, by turning off the defected pixel, recognition of the defect in the display device may be reduced or effectively prevented.

In an exemplary embodiment of the invention, by disposing the first electrode 130 in the same layer as the gate line 121, and electrically connecting the storage electrode line 196 disposed in the same layer as the pixel electrode 191 to the first electrode 130, a reduction of the aperture ratio in the display device due to the electrode pattern for the repair may be minimized.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a substrate;
a gate electrode on the substrate;
a first electrode separated from the gate electrode;
a gate insulating layer on the gate electrode and the first electrode;
a semiconductor on the gate electrode;
a source electrode and a drain electrode on the semiconductor and separated from each other;
a passivation layer on the source electrode and the drain electrode;
a first contact hole defined in the passivation layer and exposing the drain electrode;
a second contact hole defined in the passivation layer and exposing the first electrode;
a pixel electrode on the passivation layer and connected to the drain electrode through the first contact hole; and
a second electrode on the passivation layer and connected to the first electrode through the second contact hole,
wherein the first electrode overlaps the drain electrode.

2. The display device of claim 1, wherein the first electrode comprises:
a first end portion overlapping the second electrode;
a second end portion opposite to the first end portion and overlapping the drain electrode; and
a connection member connecting the first end portion and the second end portion to each other.

3. The display device of claim 2, wherein the drain electrode comprises:
a first portion overlapping the gate electrode;
a second portion overlapping the pixel electrode; and
a third portion overlapping the second end portion of the first electrode.

4. The display device of claim 1, wherein
the first electrode is in the same layer as the gate electrode.

5. The display device of claim 4, wherein
the second electrode is in the same layer as the pixel electrode.

6. The display device of claim 1, further comprising a storage electrode line on the passivation layer,
wherein the second electrode is connected to the storage electrode line.

7. The display device of claim 6, further comprising a gate line and a data line on the substrate,
wherein
the gate electrode is connected to the gate line, and
the source electrode is connected to the data line.

8. The display device of claim 7, wherein
the storage electrode line extends in a direction parallel to a direction in which the data line extends.

9. The display device of claim 8, wherein
the storage electrode line overlaps the data line.

10. The display device of claim 9, wherein the first electrode comprises:
a first end portion overlapping the second electrode;
a second end portion opposite to the first end portion and overlapping the drain electrode; and
a connection member connecting the first end portion and the second end portion to each other,
wherein the connection member extends in a direction parallel to a direction in which the storage electrode line extends.

11. A method of repairing a display device comprising:
short-circuiting a first electrode and a drain electrode of the display device,
wherein the display device comprises:
a substrate;
a gate electrode on the substrate;
the first electrode separated from the gate electrode;
a gate insulating layer on the gate electrode and the first electrode;
a semiconductor on the gate electrode;
a source electrode and the drain electrode on the semiconductor and separated from each other;
a passivation layer on the source electrode and the drain electrode;
a first contact hole defined in the passivation layer and exposing the drain electrode;
a second contact hole defined in the passivation layer and exposing the first electrode;
a pixel electrode on the passivation layer and connected to the drain electrode through the first contact hole; and
a second electrode on the passivation layer and connected to the first electrode through the second contact hole,
wherein the first electrode overlaps the drain electrode.

12. The method of claim 11, wherein the first electrode comprises:
a first end portion overlapping the second electrode;
a second end portion opposite to the first end portion and overlapping the drain electrode; and
a connection member connecting the first end portion and the second end portion to each other,
wherein the short-circuiting the first electrode and the drain electrode of the display device comprises irradiating a laser to the second end portion of the first electrode.

13. The method of claim 12, wherein the drain electrode comprises:
a first portion overlapping the gate electrode;
a second portion overlapping the pixel electrode; and
a third portion overlapping the second end portion of the first electrode,
wherein the short-circuiting the first electrode and the drain electrode of the display device comprises irradiating a laser to the third portion of the drain electrode.

14. The method of claim 11, wherein
the first electrode is in the same layer as the gate electrode.

15. The method of claim 14, wherein
the second electrode is in the same layer as the pixel electrode.

16. The method of claim 11, further comprising a storage electrode line on the passivation layer,
wherein the second electrode is connected to the storage electrode line.

17. The method of claim 16, wherein the display device further comprises a gate line and a data line on the substrate,
wherein
the gate electrode is connected to the gate line, and
the source electrode is connected to the data line.

18. The method of claim 17, wherein
the storage electrode line extends in a direction parallel to a direction in which the data line extends.

19. The method of claim 18, wherein
the storage electrode line overlaps the data line.

20. The method of claim 19, wherein the first electrode comprises:
a first end portion overlapping the second electrode;
a second end portion opposite to the first end portion and overlapping the drain electrode; and
a connection member connecting the first end portion and the second end portion,
wherein the connection member extends in a direction parallel to a direction in which the storage electrode line extends.
